(19) United States
(12) Patent Application Publication
(10) Pub. No.: US 2024/0280332 A1
(43) Pub. Date: Aug. 22, 2024

(54) TWO-PHASE IMMERSION-COOLING HEAT-DISSIPATION STRUCTURE HAVING SKIVED FINS

(71) Applicant: AMULAIRE THERMAL TECHNOLOGY, INC., New Taipei City (TW)

(72) Inventors: YU-WEI CHIU, New Taipei City (TW); CHING-MING YANG, New Taipei City (TW); CHUN-TE WU, New Taipei City (TW); TZE-YANG YEH, New Taipei City (TW)

(21) Appl. No.: 18/170,676

(22) Filed: Feb. 17, 2023

(51) Int. Cl. F28F 3/02

(52) U.S. Cl. CPC F28F 3/02; F28F 2215/00

(57) ABSTRACT

A two-phase immersion-cooling heat-dissipation structure having skived fins with high surface roughness includes an immersion-cooling substrate and a plurality of skived fins. The immersion-cooling substrate has a top surface and a bottom surface that are opposite to each other, the bottom surface is used for contacting a heat source immersed in a two-phase coolant, the top surface is connected with the plurality of skived fins, a center line average roughness Ra of a surface of the plurality of skived fins is greater than 10 μm, and a ten point average roughness Rz of the surface of the plurality of skived fins is greater than 20 μm, such that a ratio between a surface area of the plurality of skived fins in contact with the two-phase coolant and a volume of the plurality of skived fins is greater than 400.

### FIELD OF THE DISCLOSURE

The present disclosure relates to a heating-dissipation structure, and more particularly to a two-phase immersion-cooling heat-dissipation structure having skived fins with high surface roughness.

### BACKGROUND OF THE DISCLOSURE

Immersion-cooling technology is to directly immerse heat-generating components such as server, disk arrays, etc. in non-conductive two-phase coolant. In the process, the heat energy generated by the operation of the heat-generating component is removed by heat absorption and vaporization of the two-phase coolant. However, how to dissipate heat more effectively through the immersion-cooling technology has always been a problem to be addressed in the industry.

### SUMMARY OF THE DISCLOSURE

In response to the above-referenced technical inadequacies, the present disclosure provides a two-phase immersion-cooling heat-dissipation structure having skived fins with high surface roughness.

A two-phase immersion-cooling heat-dissipation structure having skived fins with high surface roughness is provided, including an immersion-cooling substrate and a plurality of skived fins. The immersion-cooling substrate has a top surface and a bottom surface that are opposite to each other, the bottom surface is used for contacting a heat source immersed in a two-phase coolant, the top surface is connected with the plurality of skived fins, a center line average roughness Ra of a surface of the plurality of skived fins is greater than 10 μm, and a ten-point average roughness Rz of the surface of the plurality of skived fins is greater than 20 μm, such that a ratio between a surface area of the plurality of skived fins in contact with the two-phase coolant and a volume of the plurality of skived fins is greater than 400.

In preferred embodiments, the plurality of skived fins are one of in-column fins and plate-shaped fins.

In preferred embodiments, the plurality of immersion-cooling fins are made of one of copper, copper alloy, and aluminum alloy.

In preferred embodiments, a surface of one of the plurality of skived fins is a rough machined surface formed by machining.

In preferred embodiments, a surface of one of the plurality of skived fins is a rough machined surface formed by machining.

In preferred embodiments, a surface of one of the plurality of skived fins is a rough deposition surface formed by deposition.

In preferred embodiments, a size of one of the plurality of skived fins ranges from 100 microns to 800 microns, and a gap between two adjacent skived fins of the plurality of skived fins ranges from 100 microns to 500 microns.

In preferred embodiments, a ratio of a centerline average roughness Ra of a surface of one of the plurality of skived fins to a gap of one of the plurality of skived fins ranges from 1:10 to 1:50, and a ratio of a ten-point average roughness Rz of a surface of one of the plurality of skived fins to a gap of one of the plurality of skived fins ranges from 1:10 to 1:30.

In preferred embodiments, the two-phase immersion-cooling heat-dissipation structure having skived fins with high surface roughness further includes: a high thermal conductivity structure attached to the bottom surface of the immersion-cooling substrate, such that the immersion-cooling substrate forms an indirect contact with the heat-generating component through the high thermal conductivity structure, and wherein a vacuum airtight cavity is formed inside the high thermal conductivity structure, and the vacuum airtight cavity contains liquid.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a first embodiment of the present disclosure;

FIG. 2 is a schematic cross-sectional view taken along II in FIG. 1; and

FIG. 3 is a schematic side view of a second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

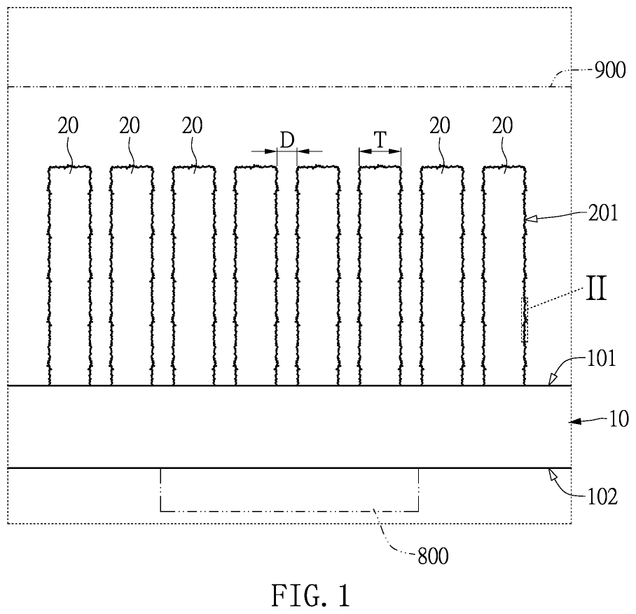

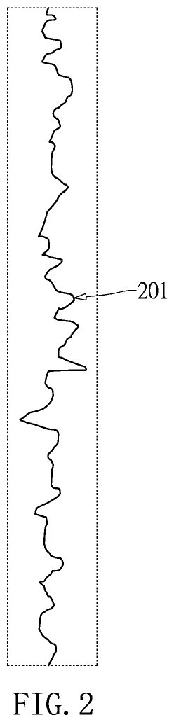

Reference is made to FIG. 1 to FIG. 2, which refer to the first embodiment of the present disclosure. The first embodiment of the present disclosure provides a two-phase immersion-cooling heat-dissipation structure having skived fins with high surface roughness, which is used for contacting a heat-generating component (heat source) immersed in a two-phase coolant. As shown in the figures, the two-phase immersion-cooling heat-dissipation structure having skived fins with high surface roughness according to the first embodiment of the present disclosure includes an immersion-cooling substrate 10 and a plurality of skived fins 20.

In the first embodiment, the immersion-cooling substrate 10 can be made of high thermal conductivity materials, such as aluminum, copper or alloys thereof. The immersion-cooling substrate 10 can be a non-porous heat sink or a porous heat sink. Preferably, the immersion-cooling substrate 10 can be a porous metal heat sink immersed in a two-phase coolant 900 such as a non-conductive electronic fluorinated liquid with a porosity greater than 8%, and can be used to increase a generation of air bubbles to strengthen the immersion cooling effect.

In the first embodiment, the immersion-cooling substrate 10 has a top surface 101 and a bottom surface 102 that are opposite to each other. The bottom surface 102 is used for contacting a heat-generating component 800 immersed in the two-phase coolant 900, and the contact can be made directly or indirectly through an interposer. The top surface 101 of the immersion-cooling substrate 10 is connected with the plurality of skived fins 20, and the plurality of skived fins 20 are integrally formed on the top surface 101 of the immersion-cooling substrate 10 in a skiving manner. Moreover, the plurality of skived fins 20 may be pin fins or plate fins, and may be made of copper, copper alloy or aluminum alloy.

Moreover, when a size of one of the plurality of skived fins 20 is small (when a thickness T is less than 800 microns), a surface area of one of the plurality of skived fins 20 in contact with the two-phase coolant 900 will greatly influence on the immersion-cooling effect. Therefore, when a center line average roughness Ra of the surface 201 of one of the plurality of skived fins 20 is greater than 10 μm and a ten-point average roughness Rz of the surface 201 of one of the plurality of skived fins 20 is greater than 20 μm, a ratio of the surface area of one of the plurality of skived fins 20 in contact with the two-phase coolant 900 to a volume of one of the plurality of skived fins 20 is greater than 400, such that the surface area for forming contact can be effectively increased by increasing the surface roughness, and the surface with high roughness is also beneficial to the generation of air bubbles and the immersion-cooling effect is further enhanced.

Furthermore, when the size (thickness T) of one of the plurality of skived fins 20 ranges from 100 microns to 800 microns and the gap D between two adjacent fins of the plurality of skived fins 20 ranges from 100 microns to 500 microns, the ratio of a centerline average roughness Ra of the surface 201 of one of the plurality of skived fins to the gap of one of the plurality of skived fins ranges from 1:10 to 1:50, and the ratio of the ten-point average roughness Rz of the surface 201 of one of the plurality of skived fins to the gap of one of the plurality of skived fins ranges from 1:10 to 1:30, so as to make the effect more pronounced.

In the first embodiment, the surface 201 of one of the plurality of skived fins 20 may be a rough surface formed by a machining process, such as shot peening. That is, hard sand grains may be used to hit the plurality of skived fins 20 at high speed to form a predetermined surface 201 on the plurality of skived fins 20.

In the first embodiment, a surface 201 of one of the plurality of skived fins 20 is a rough machined surface formed by machining. Further, the surface 201 of the plurality of skived fins 20 may be formed by a physical etching process, such as ion etching. In addition, the surface 201 of one of the plurality of skived fins 20 may be chemically etched. For example, is the surface 201 can be formed by corrosion of a chemical etching solution, and may be formed by chemical etching with a phosphoric acid-based microetch, a sulfuric acid-based microetch, or a ferric chloride etchant.

In the first embodiment, the surface 201 of one of the plurality of skived fins 20 is a rough machined surface formed by machining. Furthermore, the surface 201 of one of the plurality of skived fins 20 may be formed by liquid deposition or vapor deposition (physical or chemical vapor deposition).

### Second Embodiment

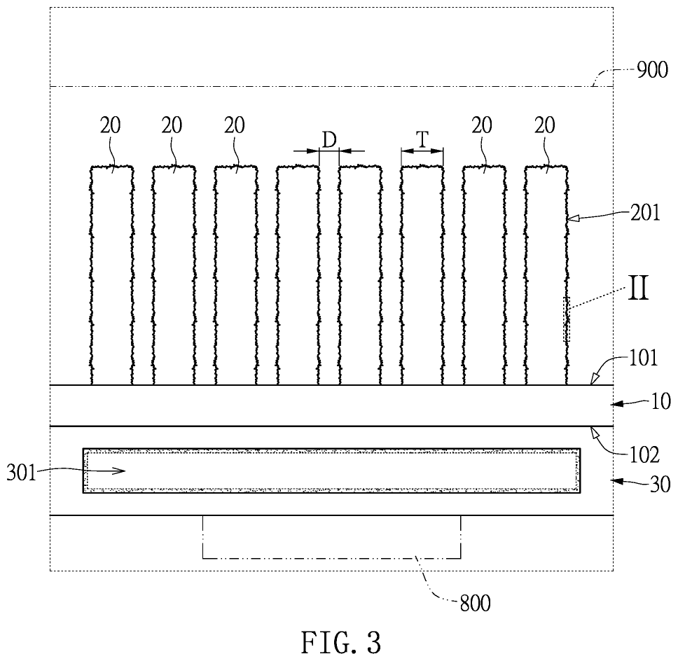

Reference is made to FIG. 3, which is the second embodiment of the present disclosure. The second embodiment is substantially the same as the first embodiment, and the differences are described as follows.

In the second embodiment, a high thermal conductivity structure 30 is further included. Moreover, the high thermal conductivity structure 30 is attached to the bottom surface 102 of the immersion-cooling substrate 10, such that the immersion-cooling substrate 10 forms an indirect contact with the heat-generating component 800 immersed in the two-phase coolant 900 through the high thermal conductivity structure 30. In detail, the high thermal conductivity structure 30 may be attached to the bottom surface 102 of the immersion-cooling substrate 10 through welding, friction stir bonding, adhesive, or diffusion bonding. In other embodiments, the immersion-cooling substrate 10 may be integrally formed with the high thermal conductivity structure 30.

Furthermore, a vacuum airtight cavity 301 is formed inside the high thermal conductivity structure 30, a sintered body can also be formed on a top wall and a bottom wall of the vacuum airtight cavity 301, and an appropriate amount of liquid is contained in the vacuum airtight cavity 401. The liquid may be water or acetone. Moreover, the bottom surface of the high thermal conductivity structure 30 can be used to contact the heat-generating component 800 immersed in the two-phase coolant 900, so that heat energy generated by the heat-generating component 800 can be absorbed and vaporized by the two-phase coolant. The high thermal conductivity structure 30 can also contact and absorb the heat energy generated by the heat-generating component 800, such that the liquid in the vacuum airtight cavity 301 can be vaporized and evaporated into steam and dissipated to the immersion-cooling substrate 10, and the heat energy is quickly transferred to the plurality of skived-fins 20 that are integrally formed with the immersion-cooling substrate 10 and very densely arranged. The two-phase coolant 900 is used to absorb and vaporize the heat energy absorbed by the plurality of skived-fins 20, while the steam in the vacuum airtight cavity 301 is released and condensed on the top wall of the vacuum airtight cavity 401, and then flows back to the bottom wall of the vacuum airtight cavity 401. Such a high-speed circulation can quickly release the heat energy generated by the heat-generating component 800, thereby enhancing the immersion-cooling effect.

In summary, the two-phase immersion-cooling heat-dissipation structure having skived fins with high surface roughness provided by the present disclosure can effectively increase the surface area of the skived fins in contact with the two-phase cooling liquid, and can facilitate the generation of air bubbles, so as to effectively enhance the overall immersion-cooling effect at least by virtue of “providing an immersion-cooling substrate,” “providing a plurality of skived fins,” “the immersion-cooling substrate having a top surface and a bottom surface that are opposite to each other,” “the bottom surface being used for contacting a heat source immersed in a two-phase coolant, the top surface being connected with the plurality of skived fins,” “a center line average roughness Ra of a surface of the plurality of skived fins being greater than 10 μm,” and “a ten-point average roughness Rz of the surface of the plurality of skived fins being greater than 20 μm, such that a ratio between a surface area of the plurality of skived fins in contact with the two-phase coolant and a volume of the plurality of skived fins is greater than 400.”

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A two-phase immersion-cooling heat-dissipation structure having skived fins with high surface roughness, including an immersion-cooling substrate and a plurality of skived fins, wherein the immersion-cooling substrate has a top surface and a bottom surface that are opposite to each other, the bottom surface is used for contacting a heat source immersed in a two-phase coolant, the top surface is connected with the plurality of skived fins, a center line average roughness Ra of a surface of the plurality of skived fins is greater than 10 μm, and a ten-point average roughness Rz of the surface of the plurality of skived fins is greater than 20 μm, such that a ratio between a surface area of the plurality of skived fins in contact with the two-phase coolant and a volume of the plurality of skived fins is greater than 400.

2. The two-phase immersion-cooling heat-dissipation structure having skived fins with high surface roughness according to claim 1, wherein the plurality of skived fins are one of in-column fins and plate-shaped fins.

3. The two-phase immersion-cooling heat-dissipation structure having skived fins with high surface roughness according to claim 1, wherein the plurality of skived fins are made of one of copper, copper alloy, and aluminum alloy.

4. The two-phase immersion-cooling heat-dissipation structure having skived fins with high surface roughness according to claim 1, wherein a surface of one of the plurality of skived fins is a rough machined surface formed by machining.

5. The two-phase immersion-cooling heat-dissipation structure having skived fins with high surface roughness according to claim 1, wherein a surface of one of the plurality of skived fins is a rough machined surface formed by machining.

6. The two-phase immersion-cooling heat-dissipation structure having skived fins with high surface roughness according to claim 1, wherein a surface of one of the plurality of skived fins is a rough deposition surface formed by deposition.

7. The two-phase immersion-cooling heat-dissipation structure having skived fins with high surface roughness according to claim 1, wherein a size of one of the plurality of skived fins ranges from 100 microns to 800 microns, and a gap between two adjacent skived fins of the plurality of skived fins ranges from 100 microns to 500 microns.

8. The two-phase immersion-cooling heat-dissipation structure having skived fins with high surface roughness according to claim 7, wherein a ratio of a centerline average roughness Ra of a surface of one of the plurality of skived fins to a gap of one of the plurality of skived fins ranges from 1:10 to 1:50, and a ratio of a ten-point average roughness Rz of a surface of one of the plurality of skived fins to a gap of one of the plurality of skived fins ranges from 1:10 to 1:30.

9. The two-phase immersion-cooling heat-dissipation structure having skived fins with high surface roughness according to claim 1, further including: a high thermal conductivity structure attached to the bottom surface of the immersion-cooling substrate, such that the immersion-cooling substrate forms an indirect contact with the heat-generating component through the high thermal conductivity structure, and wherein a vacuum airtight cavity is formed inside the high thermal conductivity structure, and the vacuum airtight cavity contains liquid.
